(19) United States
(12) Patent Application Publication
(10) Pub. No.: US 2022/0173320 A1
(43) Pub. Date: Jun. 2, 2022

(54) MASK AND METHOD FOR PREPARING SAME, AND METHOD FOR PREPARING DISPLAY PANEL

(71) Applicant: BOE Technology Group Co., Ltd., Beijing (CN)

(72) Inventors: Kuo SHEN, Beijing (CN); Zhihui ZHANG, Beijing (CN)

(21) Appl. No.: 17/478,150

(22) Filed: Sep. 17, 2021

(30) Foreign Application Priority Data
Dec. 1, 2020 (CN) 202011387759.1

(51) Int. Cl. H01L 51/00; H01L 27/32; C23C 14/04; G03F 1/80; G03F 1/76

(52) U.S. Cl. CPC H01L 51/0011; H01L 27/3216; H01L 27/3218; C23C 14/24; G03F 1/80; G03F 1/76; C23C 14/042

(57) ABSTRACT

A mask is provided. The mask is applicable to prepare an organic functional layer of a sub-pixel in a display panel. The display panel includes a plurality of pixel units and a pixel defining layer, wherein each pixel unit includes a plurality of sub-pixels, and the pixel defining layer surrounds each sub-pixel. The mask includes a substrate and at least one photo spacer, wherein the substrate includes an opening region and a light shielding region. The opening region exposes a light emitting region of part of the sub-pixels, and the light shielding region covers the remaining sub-pixels and the pixel defining layer. The photo spacer is disposed in the light shielding region.

### CROSS-REFERENCE TO RELATED APPLICATION

This application claims priority to Chinese Patent Application No. 202011387759.1, filed Dec. 1, 2020, and entitled “MASK AND METHOD FOR PREPARING SAME, AND METHOD FOR PREPARING DISPLAY PANEL”, the content of which is incorporated herein by reference in its entirety.

### TECHNICAL FIELD

The present disclosure relates to the field of display technologies, and in particular, relates to a mask and a method for preparing the same, and a method for preparing a display panel.

### BACKGROUND

Organic light emitting diode (OLED) display panels have become a main development direction in the display field, due to the advantages of thinness, self-illumination, wide viewing angle, fast response speed, low luminance, low power consumption, and the like.

In the related art, an OLED display panel includes a substrate, and a plurality of sub-pixels of different colors disposed on one side of the substrate. Each sub-pixel includes an anode, a light emitting layer, and a cathode. The light emitting layer of each sub-pixel in the OLED display panel may be prepared through an evaporation process. For example, the light emitting layer of each sub-pixel in the OLED display panel may be obtained by using a fine metal mask (FMM) through an evaporation process.

### SUMMARY

The present disclosure provides a mask and a method for preparing the same, and a method for preparing a display panel. The technical solutions are as follows.

In one aspect, a mask is provided. The mask is applicable to prepare an organic functional layer of a sub-pixel in a display panel, wherein the display panel includes a plurality of pixel units, each of the pixel units comprising a plurality of sub-pixels, and the display panel further includes a pixel defining layer surrounding each of the sub-pixels. The mask includes: a substrate, comprising an opening region and a light shielding region, wherein the opening region exposes light emitting regions of part of the sub-pixels, and the light shielding region covers the remaining sub-pixels and the pixel defining layer; and at least one photo spacer, wherein the at least one photo spacer is connected to the substrate and is disposed in the light shielding region.

Optionally, a position of the at least one photo spacer in the light shielding region corresponds to the pixel defining layer.

Optionally, the mask includes a plurality of photo spacers, wherein a position of each of the photo spacers in the light shielding region corresponds to portion, which is in one of the pixel units, of the pixel defining layer.

Optionally, a number of the photo spacers is equal to a number of the pixel units, the plurality of photo spacers are in one-to-one correspondence with the plurality of pixel units, and the position of each of the photo spacers in the light shielding region corresponds to a portion, which is in a corresponding pixel unit, of the pixel defining layer.

Optionally, each of the pixel units includes a first sub-pixel, a second sub-pixel, and a third sub-pixel, and the pixel defining layer surrounds the first sub-pixel, the second sub-pixel, and the third sub-pixel;

the opening region of the substrate exposes a light emitting region of the first sub-pixel, the light shielding region of the substrate covers the second sub-pixel, the third sub-pixel, and the pixel defining layer, and the position of the photo spacer in the light shielding region corresponds to a portion, between the second sub-pixel and the third sub-pixel in the pixel unit, of the pixel defining layer.

Optionally, the first sub-pixel is a red sub-pixel, the second sub-pixel is a green sub-pixel, and the third sub-pixel is a blue sub-pixel.

Optionally, the first sub-pixel is a green sub-pixel, the second sub-pixel is a red sub-pixel, and the third sub-pixel is a blue sub-pixel.

Optionally, the first sub-pixel is a blue sub-pixel, the second sub-pixel is a red sub-pixel, and the third sub-pixel is a green sub-pixel.

Optionally, a material of the photo spacer is an organic material or a metal material.

Optionally, a material of the photo spacer is the same as a material of the substrate.

Optionally, the material of the photo spacer and the material of the substrate are both Invar.

In another aspect, a method for preparing a display panel is provided. The method includes: preparing a pixel defining layer on a back plate, wherein the pixel defining layer defines a plurality of sub-pixels in each of a plurality of pixel units; covering the back plate with a mask, wherein the mask includes: a substrate and at least one photo spacer, the substrate comprising an opening region and a light shielding region, and the at least one photo spacer being connected to the substrate and disposed in the light shielding region, wherein the opening region exposes a light emitting region of part of the sub-pixels, the light shielding region covers the remaining sub-pixels and the pixel defining layer, and the at least one photo spacer abuts against the back plate; and forming an organic functional layer in the light emitting region of the sub-pixel exposed from the opening region.

Optionally, covering the back plate with the mask includes: disposing the mask on a side of the pixel defining layer away from the back plate, wherein the at least one photo spacer abuts against the pixel defining layer.

Optionally, the mask includes a plurality of photo spacers, each of the photo spacers abutting against a portion, which is in one of the pixel units, of the pixel defining layer.

Optionally, each of the pixel units includes a first sub-pixel, a second sub-pixel, and a third sub-pixel, the pixel defining layer surrounds the first sub-pixel, the second sub-pixel, and the third sub-pixel; the opening region of the substrate exposes a light emitting region of the first sub-pixel, and the light shielding region of the substrate covers the second sub-pixel, the third sub-pixel, and the pixel defining layer; and at least one of the photo spacers abuts against a portion, between the second sub-pixel and the third sub-pixel in the pixel unit, of the pixel defining layer.

In still another aspect, a method for preparing a mask is provided. The method includes: forming a substrate comprising an opening region, wherein a region, other than the opening region, of the substrate is a light shielding region; and forming at least one photo spacer in the light shielding region of the substrate.

Optionally, forming the at least one photo spacer includes: coating the light shielding region of the substrate with photoresist; and removing part of the photoresist through exposure and development, such that the remaining photoresist forms the at least one photo spacer.

Optionally, forming the at least one photo spacer includes: coating the light shielding region of the substrate with photoresist; removing part of the photoresist through exposure and development; forming the at least one photo spacer through an electroforming process at a position where the photoresist is removed; and removing the remaining photoresist.

Optionally, forming the substrate comprising the opening region includes: coating the substrate with photoresist; removing part of the photoresist through exposure and development; forming the opening region through etching at a position where the photoresist is removed; and removing the remaining photoresist, to form the substrate comprising the opening region.

Optionally, forming the substrate comprising an opening region comprises: coating a base plate with photoresist; removing part of the photoresist through exposure and development; forming the light shielding region through an electroforming process at a position where the photoresist is removed; and removing the remaining photoresist, to form the substrate comprising the opening region.

It is to be understood that both the foregoing general descriptions and the following detailed descriptions are exemplary and explanatory only and are not restrictive of the present disclosure.

### BRIEF DESCRIPTION OF THE DRAWINGS

The accompanying drawings herein are incorporated in and constitute a part of this description of the present disclosure, showing embodiments consistent with the present disclosure, and explaining the principles of the present disclosure together with the description. Apparently, the accompanying drawings in the following descriptions are only some embodiments of the disclosure and other drawings may also be derived from the accompanying drawings by persons of ordinary skill in the art without the creative effort.

FIG. 1 is a top view of a display panel in accordance with an embodiment of the present disclosure;

FIG. 2 is a cross-sectional view of a display panel in accordance with an embodiment of the present disclosure;

FIG. 3 is a top view of a mask in accordance with an embodiment of the present disclosure;

FIG. 4 is a top view of a mask when attached to a back plate of a display panel in accordance with an embodiment of the present disclosure;

FIG. 5 is a cross-sectional view of a mask when attached to a back plate of a display panel in accordance with an embodiment of the present disclosure;

FIG. 6 is a top view of another mask in accordance with an embodiment of the present disclosure;

FIG. 7 is a top view of another mask when attached to a back plate of a display panel in accordance with an embodiment of the present disclosure;

FIG. 8 is a cross-sectional view of another mask when attached to a back plate of a display panel in accordance with an embodiment of the present disclosure;

FIG. 9 is a top view of yet another mask in accordance with an embodiment of the present disclosure;

FIG. 10 is a top view of yet another mask when being attached to a back plate of a display panel in accordance with an embodiment of the present disclosure;

FIG. 11 is a cross-sectional view of yet another mask when attached to a back plate of a display panel in accordance with an embodiment of the present disclosure;

FIG. 12 is a flow chart of a method for preparing a display panel in accordance with an embodiment of the present disclosure;

FIG. 13 is a flow chart of a method for preparing a mask in accordance with an embodiment of the present disclosure;

FIG. 14 is a schematic diagram of a first method for preparing a substrate in a mask in accordance with an embodiment;

FIG. 15 is a schematic diagram of a second method for preparing a substrate in a mask in accordance with an embodiment;

FIG. 16 is a schematic diagram of a first method for preparing a photo spacer in a mask in accordance with an embodiment; and

FIG. 17 is a schematic diagram of a second method for preparing a photo spacer in a mask in accordance with an embodiment.

Reference numerals and denotation thereof in the figures:

1—substrate;

101—opening region;

102—light shielding region;

12—photo spacer;

2—back plate;

20—pixel unit;

201—red sub-pixel;

202—green sub-pixel;

203—blue sub-pixel;

21—pixel defining layer;

3—base plate; and

4—photoresist.

### DETAILED DESCRIPTION

Example embodiments are described more comprehensively with reference to the accompanying drawings. The example embodiments may be implemented in various forms and should not be construed as a limitation to the embodiments set forth herein. Rather, the embodiments are set forth to provide a thorough and complete disclosure, and to fully convey the concepts of the example embodiments to those skilled in the art. Similar reference numerals in the drawings represent the same or similar structures, and detailed descriptions thereof are omitted.

In the related art, when a light emitting layer of each sub-pixel in an OLED display panel is prepared, a photo spacer (PS) may be prepared on the substrate of the OLED display panel to support the fine metal mask (FMM), such that a gap is formed between the substrate and the FMM. In this way, the substrate and FMM may be prevented from being attached to each other too closely, thereby avoiding damage to evaporated film layers in subsequent separation.

However, the FMM needs to be attached to the substrate as closely as possible during alignment, to avoid formation of a big shadow caused by a big gap. The FMM is likely to scratch or crush the photo spacer on the substrate during alignment, and the damaged photo spacer may affect the evaporation effect on the subsequent film layers. For example, the cathode of a sub-pixel is easily subject to breakage, resulting in poor pixel or local encapsulation failure and affecting the performance and lifetime of the device. In addition, the photo spacer may also scratch the FMM during alignment, resulting in poor evaporation.

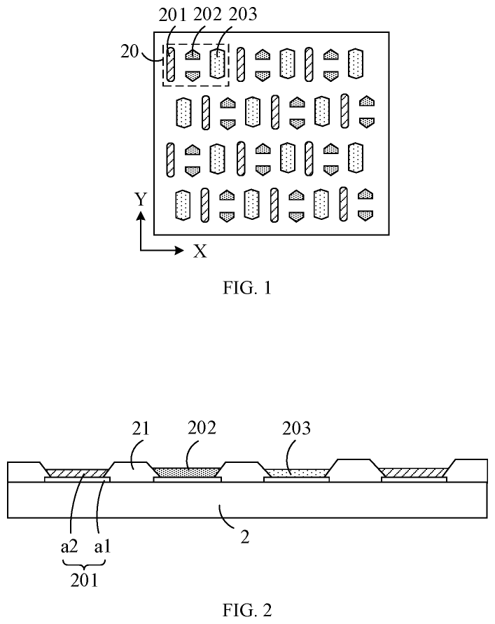

FIG. 1 is a top view of a display panel in accordance with an embodiment of the present disclosure. FIG. 2 is a cross-sectional view of a display panel in accordance with an embodiment of the present disclosure. In conjunction with FIGS. 1 and 2, the display panel includes a plurality of pixel units 20 and a pixel defining layer 21. Each pixel unit 20 includes a plurality of sub-pixels. For example, FIGS. 1 and 2 each show a red (R) sub-pixel 201, a green (G) sub-pixel 202, and a blue (B) sub-pixel 203. Each sub-pixel includes an anode a1, a light emitting layer a2, and a cathode (not shown in the figures). The pixel defining layer 21 has a hollow region and the pixel defining layer 21 is disposed on the anode a1 of the sub-pixel. The hollow region of the pixel defining layer 21 may expose at least a portion of the anode a1 of the sub-pixel, and the light emitting layer a2 of the sub-pixel is configured to be disposed in the hollow region. That is, the hollow region may define the light emitting region of each sub-pixel.

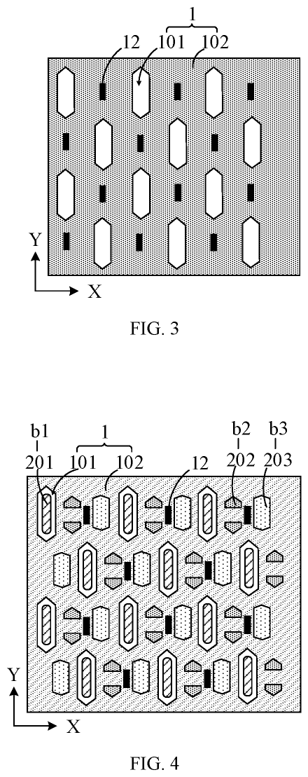

FIG. 3 is a top view of a mask in accordance with an embodiment of the present disclosure. Referring to FIG. 3, the mask includes a substrate 1 and at least one photo spacer 12 connected to the substrate 1. Here, a plurality of photo spacers 12 are shown in FIG. 3. The substrate 1 has an opening region 101 and a light shielding region 102. The opening region 101 is configured to expose a light emitting region of part of the sub-pixels on the display panel, and the light shielding region 102 is configured to cover the remaining sub-pixels on the display panel and the pixel defining layer 21 for defining the sub-pixels. The photo spacers 12 are disposed in the light shielding region 102.

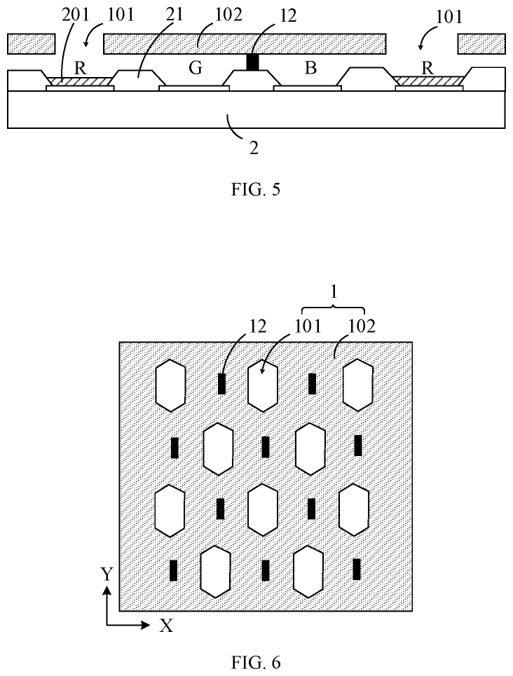

Referring to FIGS. 4 and 5, the opening region 101 is configured to expose the light emitting region of part of the sub-pixels on the display panel, and the light shielding area 102 is configured to cover the remaining sub-pixels on the display panel and the pixel defining layer 21 for defining the sub-pixels. That is, when the mask is used to prepare the display panel, the back plate 2 of the display panel is first covered with the mask, such that the opening region 101 may expose the light emitting region of part of the sub-pixels on the display panel, and the light shielding region 102 may cover the remaining sub-pixels and the pixel defining layer 21.

Thus, the organic functional layer may be evaporated in the light emitting region of the sub-pixel exposed from the opening region 101, to evaporate the film layer of the corresponding sub-pixel. The film layers of all sub-pixels may be evaporated with a mask by using the same method according to the same principle.

In the embodiment of the present disclosure, since the photo spacer 12 is prepared directly on the substrate 1 of the mask, the photo spacer 12 may abut against the back plate 2 of the display panel to support the substrate 1 when the back plate 2 of the display panel is covered with the mask. Also, even if the photo spacer 12 is scratched or crushed when the mask and the back plate 2 are attached to each other, the photo spacer 12 can be separated from the back plate 2 when the mask is taken away later, without affecting the evaporation of subsequent film layers (e.g., evaporation of the cathode of the sub-pixel), which ensures the evaporation and encapsulation effects of the display panel. Here, the material of the cathode of the sub-pixel may be a metallic material.

In summary, the embodiment of the present disclosure provides a mask. The mask includes a substrate and at least one photo spacer. When the display panel is prepared using the mask, the photo spacer can abut against the back plate of the display panel to support the substrate. In addition, even if the photo spacer is scratched or crushed, the photo spacer can be separated from the back plate when the mask is taken away later, without affecting the evaporation of subsequent film layers, which ensures the evaporation and encapsulation effects of the display panel.

In some embodiments, the organic functional layer may include a light emitting layer, a hole transport layer, an electron transport layer, a hole injection layer, an electron injection layer, a hole blocking layer, and an electron blocking layer. That is, the mask provided in the embodiment of the present disclosure may be used to evaporate the light emitting layer, the hole transport layer, the electron transport layer, the hole injection layer, the electron injection layer, the hole blocking layer, and the electron blocking layer of the sub-pixel.

In the embodiment of the present disclosure, the photo spacer 12 may be disposed at any position of the light shielding region 102, so long as the photo spacer 12 can abut against the back plate 2 when the mask is attached to the back plate 2 of the display panel. In an implementation, as shown in FIGS. 4 and 5, the position of the at least one photo spacer 12 of the mask in the light shielding region 102 may correspond to the pixel defining layer. That is, when the mask is attached to the back plate 2 of the display panel, the photo spacer 12 abuts against the pixel defining layer 21, such that the photo spacer 12 is prevented from damaging the evaporated film layers, anodes or the like in the sub-pixels covered by the light shielding region 12.

Referring to FIGS. 3 and 4, the mask includes a plurality of photo spacers 12, and the position of each photo spacer in the light shielding region 12 corresponds to the portion, which is in one pixel unit 20, of the pixel defining layer 21. For example, the number of photo spacers 12 is equal to the number of pixel units 20, and the plurality of photo spacers 12 in the mask are in one-to-one correspondence with the plurality of pixel units 20 in the display panel. The position of each photo spacer 12 in the light shielding region 12 corresponds to the portion, which is in a corresponding pixel unit 20, of the pixel defining layer 21.

That is, one photo spacer 12 is provided for each pixel unit 20, and the photo spacer 12 corresponds to the portion, which is in the pixel unit 20, of the pixel defining layer 21. In this way, there may be enough photo spacers 12 to abut against the back plate 2 of the display panel, so as to play a uniform support effect, without the difficulty of preparing the photo spacers 12 due to the large amount. In other implementations, one photo spacer 12 may be provided for each several pixel units 20, or a plurality of photo spacers 12 may be provided for each pixel unit 20.

Referring to FIG. 4, a plurality of pixel units 20 are disposed in an array on the display panel. Each pixel unit 20 may include a first sub-pixel b1, a second sub-pixel b2, and a third sub-pixel b3. Here, the colors of the first sub-pixel b1, the second sub-pixel b2, and the third sub-pixel b3 are different from each other.

The opening region 101 of the substrate 1 of the mask may be configured to expose the light emitting region of the first sub-pixel b1, and the light shielding region 102 of the substrate 1 may be configured to cover the second sub-pixel b2, the third sub-pixel b3, and the pixel defining layer 21. The position of the photo spacer 12 in the light shielding region 102 corresponds to the portion, between the second sub-pixel b2 and the third sub-pixel b3 in the pixel unit 20, of the pixel defining layer 21.

In addition, the pixel defining layer 21 surrounds the first sub-pixel b1, the second sub-pixel b2 and the third sub-pixel b3. That is, among the hollow regions of the pixel defining layer 21, the first hollow region may expose at least a portion of the anode of the first sub-pixel b1, the second hollow region may expose at least a portion of the anode of the second sub-pixel b2, and the third hollow region may expose at least a portion of the anode of the third sub-pixel b3.

In the embodiment of the present disclosure, each pixel unit 20 includes a red sub-pixel 201, a green sub-pixel 202, and a blue sub-pixel 203. Referring to FIG. 1, the red sub-pixel 201, the green sub-pixel 202, and the blue sub-pixel 203 are arranged in a horizontal direction X. The green sub-pixels 202 include a first green sub-pixel 202 and a second green sub-pixel 202 arranged in a vertical direction Y. The region between the sub-pixels is covered by the pixel defining layer 21, that is, the light emitting region of each sub-pixel is defined by the pixel defining layer 21.

In some embodiments, the organic functional layer (e.g., light emitting layer) of the sub-pixel of each color needs to be evaporated with a separate mask. That is, the sub-pixel 201 of each color may be the first sub-pixel b1, and the organic functional layer of the sub-pixel of the color may be evaporated with a corresponding mask.

As an optional implementation, referring to FIG. 4, assuming that the first sub-pixel is the red sub-pixel 201, the second sub-pixel is the green sub-pixel 202, and the third sub-pixel is the blue sub-pixel 203, then evaporation of the light emitting layer of the red sub-pixel is taken as an example.

Referring to FIGS. 3-5, the opening region 101 of the mask is configured to expose the light emitting region of the red sub-pixel 201, and the light shielding region 102 is configured to cover the green sub-pixel 202, the blue sub-pixel 203, and the pixel defining layer 21. The photo spacer 12 is disposed in the light shielding region 102.

In some embodiments, the photo spacer 12 may be disposed at any position of the light shielding region 102, so long as the photo spacer 12 abuts against the back plate 2 when the mask is attached to the back plate 2 of the display panel. In an implementation, as shown in FIGS. 4 and 5, the position of the photo spacer 12 in the light shielding region 102 corresponds to the pixel defining layer 21. That is, when the mask is attached to the back plate 2 of the display panel, the photo spacer 12 abuts against the pixel defining layer 21, such that the photo spacer 12 is prevented from damaging the evaporated film layer or anode in the green sub-pixel 202 or the blue sub-pixel 203.

For example, as illustrated in FIGS. 4 and 5, the position of the photo spacer 12 in the light shielding region 102 corresponds to the portion, between the green sub-pixel 202 and the blue sub-pixel 203, of the pixel defining layer 21. That is, when the mask is attached to the back plate 2 of the display panel, the photo spacer 12 abuts against the portion, between the green sub-pixel 202 and the blue sub-pixel 203, of the pixel defining layer 21. There is sufficient space between the green sub-pixel 202 and the blue sub-pixel 203 for abutting the photo spacer 12. The photo spacer 12 may be made thick in order to provide good support. In addition, the position of the photo spacer 12 on the mask is substantially in the middle between two opening regions 101 respectively corresponding to two adjacent red sub-pixels 201 arranged along the horizontal direction X, such that there is sufficient space to prepare the photo spacer 12, which facilitates processing of the mask.

As another optional implementation, referring to FIGS. 6-8, assume that the first sub-pixel b1 is the green sub-pixel 202, the second sub-pixel b2 is the red sub-pixel 201, and the third sub-pixel b3 is the blue sub-pixel 203, then evaporation of the light emitting layer of the green sub-pixel 202 is taken as an example.

Referring to FIGS. 6-8, the opening region 101 of the mask is configured to expose the light emitting region of the green sub-pixel 202, and the light shielding region 102 is configured to cover the red sub-pixel 201, the blue sub-pixel 203, and the pixel defining layer 21. The photo spacer 12 is disposed in the light shielding region 102.

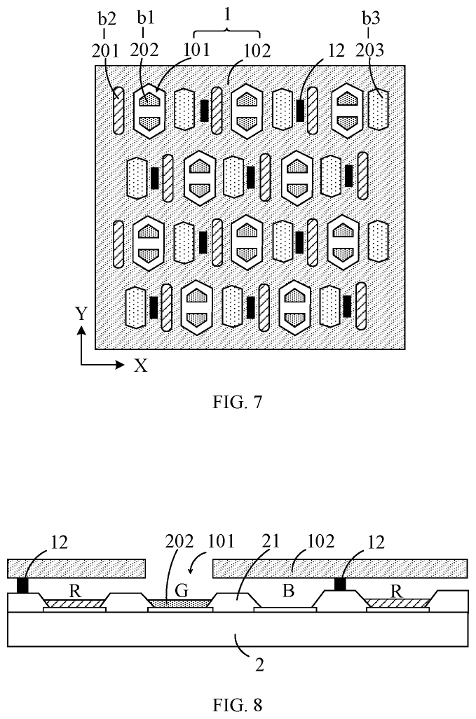

In an implementation, as shown in FIGS. 7 and 8, the position of the photo spacer 12 in the light shielding region 102 corresponds to the pixel defining layer 21. That is, when the mask is attached to the back plate 2 of the display panel, the photo spacer 12 abuts against the pixel defining layer 21, such that the photo spacer 12 is prevented from damaging the evaporated film layer or anode in the red sub-pixel 201 or the blue sub-pixel 203.

For example, as illustrated in FIGS. 7 and 8, the position of the photo spacer 12 in the light shielding region 102 corresponds to the portion, between the red sub-pixel 201 and the blue sub-pixel 203, of the pixel defining layer 21. That is, when the mask is attached to the back plate 2 of the display panel, the photo spacer 12 abuts against the portion, between the red sub-pixel 201 and the blue sub-pixel 203, the pixel defining layer 21. There is sufficient space between the red sub-pixel 201 and the blue sub-pixel 203 for abutting the photo spacer 12. The photo spacer 12 may be made thick to provide good support. In addition, the position of the photo spacer 12 on the mask is substantially in the middle between two opening regions 101 respectively corresponding to two adjacent green sub-pixels 202 arranged along the horizontal direction X, such that there is sufficient space to prepare the photo spacer 12, which facilitates processing of the mask.

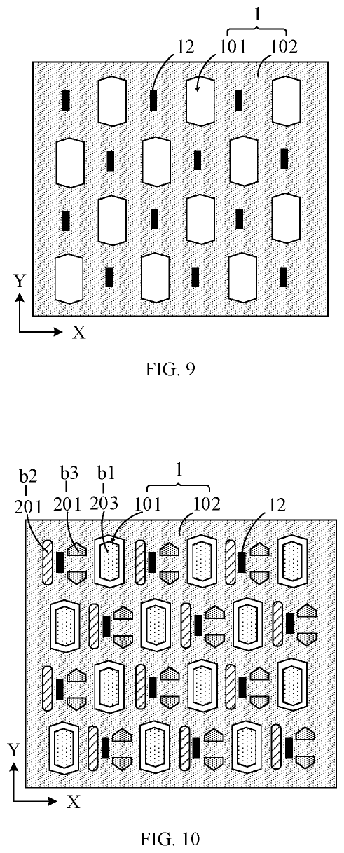

As yet another optional implementation, referring to FIGS. 9-11, assuming that the first sub-pixel is the blue sub-pixel 203, the second sub-pixel is the red sub-pixel 201, and the third sub-pixel is the green sub-pixel 202, then evaporation of the light emitting layer of the blue sub-pixel 203 is taken as an example.

Referring to FIGS. 9-10, the opening region 101 of the mask is configured to expose the light emitting region of the blue sub-pixel 203, and the light shielding region 102 is configured to cover the red sub-pixel 201, the green sub-pixel 202, and the pixel defining layer 21. The photo spacer 12 is disposed in the light shielding region 102.

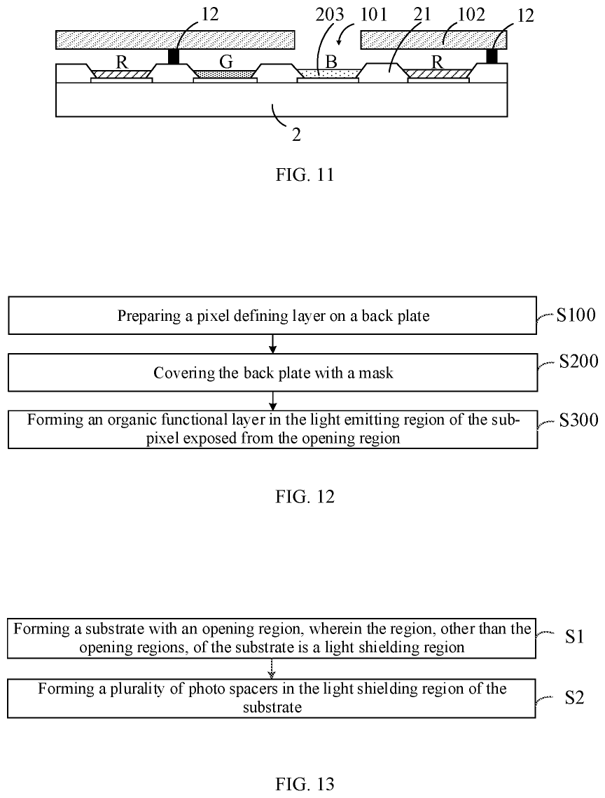

In an implementation, as shown in FIGS. 10 and 11, the position of the photo spacer 12 in the light shielding region 102 corresponds to the pixel defining layer 21. That is, when the mask is attached to the back plate 2 of the display panel, the photo spacer 12 abuts against the pixel defining layer 21, such that the photo spacer 12 is prevented from damaging the evaporated film layer, the anode or the like in the red sub-pixel 201 or the green sub-pixel 202.

For example, as illustrated in FIGS. 10 and 11, the position of the photo spacer 12 in the light shielding region 102 corresponds to the portion, between the red sub-pixel 201 and the green sub-pixel 202, of the pixel defining layer 21. That is, when the mask is attached to the back plate 2 of the display panel, the photo spacer 12 abuts against the portion, between the red sub-pixel 201 and the green sub-pixel 202, the pixel defining layer 21. There is sufficient space between the red sub-pixel 201 and the green sub-pixel 202 for abutting the photo spacer 12. The photo spacer 12 may be made thick to provide good support. In addition, the position of the photo spacer 12 on the mask is substantially in the middle between two opening regions 101 respectively corresponding to two adjacent blue sub-pixels 203 arranged along the horizontal direction X, such that there is sufficient space to prepare the photo spacer 12, which facilitates processing of the mask.

In the above implementations, the positional relationship between the photo spacers 12 and each of the sub-pixels in the corresponding pixel unit 20 is consistent. That is, the photo spacer 12 and the sub-pixels in the pixel unit 20 are arranged along the horizontal direction X, and the photo spacer 12 is in the center of the pixel unit 20 in the vertical direction Y, such that there is sufficient space for the photo spacer 12.

In other implementations, the photo spacer 12 may also be in the upper center or lower center of the pixel unit 20 in the vertical direction Y or even at any position of the light shielding region 102 in the pixel unit 20. For example, the green sub-pixel 202 includes a first green sub-pixel 202 and a second green sub-pixel 202 arranged in the vertical direction. In the mask used to evaporate the red sub-pixel 201 or the blue sub-pixel 203, the photo spacer 12 may also be disposed between the first green sub-pixel 202 and the second green sub-pixel 202. Generally, the position and number of the photo spacer 12 can be determined based on the space and preparation complexity.

In the embodiment of the present disclosure, the photo spacer shown in the top view is rectangular. However, the shape of the photo spacer is not limited in the present disclosure, and the photo spacer may also be circular, oval, trapezoidal, or the like. Similarly, the dimension of the photo spacer is not limited in the present disclosure, either.

In some embodiments, the material of the photo spacer 12 may be an organic material or a metallic material. In addition, the material of the photo spacer 12 is the same as the material of the substrate 1, to facilitate preparation, without affecting the overall net stretching and deformation capability of the mask. For example, the materials of the photo spacer 12 and the substrate 1 may be Invar.

In the embodiments of the present disclosure, covering the sub-pixel by the light shielding region 102 may refer to that the light shielding region 102 is configured to cover the anode of the sub-pixel, or a formed organic functional layer of the sub-pixel.

In summary, the embodiment of the present disclosure provide a mask. The mask includes a substrate and at least one photo spacer. When the display panel is prepared using the mask, the photo spacer can abut against the back plate of the display panel to support the substrate. In addition, even if the photo spacer is scratched or crushed, the photo spacer can be separated from the back plate when the mask is taken away later, without affecting the evaporation of subsequent film layers, which ensures the evaporation and encapsulation effects of the display panel.

FIG. 12 is a flowchart of a method for preparing a display panel in accordance with an embodiment of the present disclosure. Referring to FIG. 12, the method may include the following steps.

In S100, a pixel defining layer 21 is prepared on a back plate 2.

The back plate 2 is a drive back plate 2 on which a pixel drive circuit is formed. The pixel defining layer 21 defines a plurality of sub-pixels in each of a plurality of pixel units 20.

The anode (the anode also be referred to as a pixel electrode) of each sub-pixel is formed prior to forming the pixel defining layer 21. Then, the pixel defining layer 21 is formed. The pixel defining layer 21 has a hollow region. The pixel defining layer 21 covers the edge of the anode, such that at least a portion of the anode of the sub-pixel is exposed from the hollow region. The light emitting layer of the sub-pixel is disposed in the hollow region, that is, the light emitting region of each sub-pixel is defined by the hollow region. The pixel defining layer 21 may be made from an organic material such as photoresist 4 through exposure and development.

In S200, the back plate 2 is covered with a mask.

The mask includes a substrate 1 and at least one photo spacer 12. The substrate 1 has an opening region 101 and a light shielding region 102. The at least one photo spacer 12 is connected to the substrate 1, and the at least one photo spacer 12 is disposed in the light shielding region 102.

In the embodiment of the present disclosure, when the back plate 2 is covered with the mask, the back plate 2 and the mask are attached to each other under the effect of magnetic force of a magnetic field, such that the opening region 101 exposes the light emitting region of part of the sub-pixels, and the light shielding region 102 covers the remaining sub-pixels and the pixel defining layer 21, and the at least one photo spacer 12 abuts against the back plate 2. The mask is disposed on the side of the pixel defining layer away from the back plate 2, and the at least one photo spacer 12 may abut against the pixel defining layer 21.

The opening regions 101 of the mask are in one-to-one correspondence with the first sub-pixels, and the light shielding region 102 covers the second sub-pixels, the third sub-pixels and the pixel defining layer 21. The photo spacer 12 abuts against the portion, between the second sub-pixel and the third sub-pixel, of the pixel defining layer 21, to maintain a slight gap between the mask and the back plate 2.

For example, the light emitting layer of the red sub-pixel 201 is evaporated (that is, the first sub-pixel is the red sub-pixel 201). The opening regions 101 of the mask are in one-to-one correspondence with the red sub-pixels 201, and the light shielding region 102 covers the green sub-pixels 202, the blue sub-pixels 203, and the pixel defining layer 21. The photo spacer 12 abuts against the portion, between the green sub-pixel 202 and the blue sub-pixel 203, of the pixel defining layer 21, to maintain a slight gap between the mask and the back plate 2.

Similarly, when the light emitting layer of the green sub-pixel is evaporated, the mask is replaced with the mask (for example, the mask shown in FIG. 6) corresponding to the green sub-pixel. When the light emitting layer of the blue sub-pixel is evaporated, the mask is replaced with the mask (for example, the mask shown in FIG. 9) corresponding to the blue sub-pixel.

In S300, an organic functional layer is formed in the light emitting region of the sub-pixel exposed from the opening region 101.

In the embodiment of the present disclosure, the organic functional layer (for example, the light emitting layer) of the sub-pixel may be formed in the light emitting region of the sub-pixel exposed from the opening region 101 through an evaporation process. For example, by taking evaporation of the light emitting layer of the red sub-pixel 201 as an example, the light emitting layer of the red sub-pixel 201 may be formed in the light emitting region of the red sub-pixel 201 exposed from the opening region 101 through an evaporation process. The material of the light emitting layer of the red sub-pixel may be a red light emitting material.

Similarly, when the organic functional layer of the green sub-pixel is evaporated, the mask is replaced with the mask corresponding to the green sub-pixel, and the organic functional layer of the green sub-pixel is formed in the light emitting region of the green sub-pixel exposed from the opening region 101 of the mask. When the organic functional layer of the blue sub-pixel is evaporated, the mask is replaced with the mask corresponding to the blue sub-pixel, and the organic functional layer of the blue sub-pixel is formed in the light emitting region of the blue sub-pixel exposed from the opening region 101 of the mask.

In summary, the embodiment of the present disclosure provides a method for preparing a display panel. According to this method, the photo spacer of the mask is enabled to abut against the back plate of the display panel to support the substrate of the mask. In addition, even if the photo spacer is scratched or crushed, the photo spacer can be separated from the back plate when the mask is taken away later, without affecting the evaporation of subsequent film layers, which ensures the evaporation and encapsulation effects of the display panel.

FIG. 13 is a flow chart of a method for preparing a mask in accordance with an embodiment of the present disclosure. Referring to FIG. 13, the method may include the following steps.

In S1, a substrate 1 with an opening region 101 is formed, wherein the region, other than the opening region 101, of the substrate 1 is a light shielding region 102.

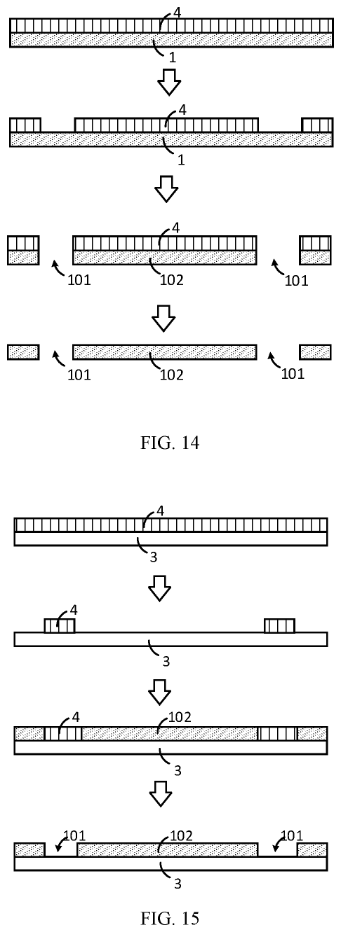

In an implementation, referring to FIG. 14, forming the substrate 1 with the opening region 101 may include: coating the substrate 1 with photoresist 4; removing part of the photoresist 4 through exposure and development; forming, by taking the remaining photoresist 4 as a mask, the opening region 101 through etching at a position where the photoresist 4 is removed; and removing the remaining photoresist 4, such that the region where the opening region 101 is not formed is the light shielding region 102. In this way, the substrate 1 with the opening region 101 is formed.

In another implementation, referring to FIG. 15, forming the substrate 1 with the opening region 101 may include: coating a base plate 3 with photoresist 4; removing part of the photoresist 4 through exposure and development; forming, by taking the remaining photoresist 4 as a mask, a layer of mask material through an electroforming process at the position where the photoresist 4 is removed, wherein the mask material is used as the light shielding region 102 of the mask; removing the remaining photoresist 4, such that the region where the mask material is not formed is the opening region 101; and finally removing the substrate 1 with the opening region 101 from the base plate 3. The material of the base plate 3 may be the same as the material of the substrate 1 of the mask.

In S2, a plurality of photo spacers 12 are formed in the light shielding region 102 of the substrate 1.

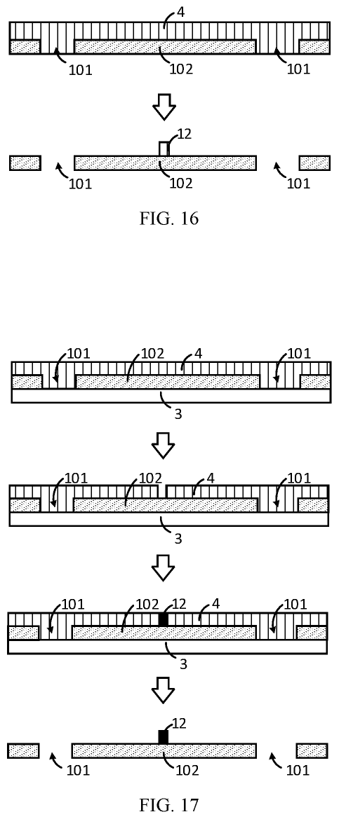

In an implementation, referring to FIG. 16, forming the plurality of photo spacers 12 may include: coating the light shielding region 102 of the substrate 1 with photoresist 4; and removing part of the photoresist 4 through exposure and development, such that the remaining photoresist 4 forms the photo spacers 12. That is, the material of the photo spacers 12 is photoresist.

In an implementation, referring to FIG. 17, forming the plurality of photo spacers 12 may include: coating the light shielding region 102 of the substrate 1 with photoresist 4; removing part of the photoresist 4 through exposure and development; forming, by taking the remaining photoresist 4 as a mask, the photo spacers 12 with metal or the like through an electroforming process at the position where the photoresist 4 is removed; and removing the remaining photoresist 4. That is, the material of the photo spacers 12 is metal or the like.

It is to be noted that the two technical solutions in S1 and the two technical solutions in S2 may be combined freely. For example, the substrate 1 with an opening region may be prepared through a first etching process in S1, and then the photo spacers 12 may be prepared with the photoresist 4 through exposure and development in S2, or the photo spacers 12 may also be prepared through an electroforming process. Similarly, the substrate 1 with the opening region may be prepared through a second electroforming process in S1, and then the photo spacers 12 may be prepared with the photoresist 4 through exposure and development in S2, or the photo spacers 12 may also be prepared through an electroforming process.

In summary, the embodiment of the present disclosure provides a method for preparing a mask. The mask includes a substrate and at least one photo spacer. When the display panel is prepared using the mask, the photo spacer can abut against the back plate of the display panel to support the substrate. In addition, even if the photo spacer is scratched or crushed, the photo spacer can be separated from the back plate when the mask is taken away later, without affecting the evaporation of subsequent film layers, which ensures the evaporation and encapsulation effects of the display panel.

Although relative terms such as “upper” and “lower” are used herein to describe the relative relationship of one component relative to another, such terms are used in the present description for convenience only, for example, to show the example directions described in the figures. It is to be understood that when the device is turned upside down, the “upper” component will be the “lower” component. When a structure is “on” another structure, the structure is integrally formed on the other structure, or the structure is “directly” disposed on the other structure, or the structure is “indirectly” disposed on the other structure by another structure.

The terms “a”, “an”, “the”, “said”, and “at least one” are intended to indicate the existence of one or more elements, components, etc. The terms “including” and “having” are intended to be inclusive and mean that there may be additional elements, components, etc., in addition to the listed elements, components, etc.

Other embodiments of the disclosure will be readily apparent to those skilled in the art from consideration of the specification and practice of the present disclosure. The present disclosure is intended to cover any variations, uses, or adaptations of the present disclosure that follow the general principles of the disclosure and include common knowledge or conventional technical means in the art which is not disclosed by the present disclosure. It is intended that the descriptions and examples are exemplary only, with the true scope and spirit of the present disclosure are indicated by the appended claims.

What is claimed is:

1. A mask, applicable to prepare an organic functional layer of a sub-pixel in a display panel, wherein the display panel comprises a plurality of pixel units, each of the pixel units comprising a plurality of sub-pixels, and the display panel further comprises a pixel defining layer surrounding each of the sub-pixels, the mask comprising:
a substrate, comprising an opening region and a light shielding region, wherein the opening region exposes a light emitting region of part of the sub-pixels, and the light shielding region covers the remaining sub-pixels and the pixel defining layer; and
at least one photo spacer, wherein the at least one photo spacer is connected to the substrate and is disposed in the light shielding region.

2. The mask of claim 1, wherein a position of the at least one photo spacer in the light shielding region corresponds to the pixel defining layer.

3. The mask of claim 2, comprising a plurality of photo spacers, wherein a position of each of the photo spacers in the light shielding region corresponds to a portion, which is in one of the pixel units, of the pixel defining layer.

4. The mask of claim 3, wherein a number of the photo spacers is equal to a number of the pixel units, the plurality of photo spacers are in one-to-one correspondence with the plurality of pixel units, and the position of each of the photo spacers in the light shielding region corresponds to a portion, which is in a corresponding pixel unit, of the pixel defining layer.

5. The mask of claim 2, wherein each of the pixel units comprises a first sub-pixel, a second sub-pixel, and a third sub-pixel, and the pixel defining layer surrounds the first sub-pixel, the second sub-pixel, and the third sub-pixel;
the opening region of the substrate exposes a light emitting region of the first sub-pixel, the light shielding region of the substrate covers the second sub-pixel, the third sub-pixel, and the pixel defining layer, and the position of the photo spacer in the light shielding region corresponds to a portion, between the second sub-pixel and the third sub-pixel in the pixel unit, of the pixel defining layer.

6. The mask of claim 5, wherein the first sub-pixel is a red sub-pixel, the second sub-pixel is a green sub-pixel, and the third sub-pixel is a blue sub-pixel.

7. The mask of claim 5, wherein the first sub-pixel is a green sub-pixel, the second sub-pixel is a red sub-pixel, and the third sub-pixel is a blue sub-pixel.

8. The mask of claim 5, wherein the first sub-pixel is a blue sub-pixel, the second sub-pixel is a red sub-pixel, and the third sub-pixel is a green sub-pixel.

9. The mask of claim 1, wherein a material of the photo spacer is an organic material or a metal material.

10. The mask of claim 1, wherein a material of the photo spacer is the same as a material of the substrate.

11. The mask of claim 10, wherein the material of the photo spacer and the material of the substrate are both Invar.

12. A method for preparing a display panel, comprising:
preparing a pixel defining layer on a back plate, wherein the pixel defining layer defines a plurality of sub-pixels in each of a plurality of pixel units;
covering the back plate with a mask, wherein the mask comprises: a substrate and at least one photo spacer, the substrate comprising an opening region and a light shielding region, and the at least one photo spacer being connected to the substrate and disposed in the light shielding region, wherein the opening region exposes a light emitting region of part of the sub-pixels, the light shielding region covers the remaining sub-pixels and the pixel defining layer, and the at least one photo spacer abuts against the back plate; and
forming an organic functional layer in the light emitting region of the sub-pixel exposed from the opening region.

13. The method of claim 12, wherein covering the back plate with the mask comprises:
disposing the mask on a side of the pixel defining layer away from the back plate, wherein the at least one photo spacer abuts against the pixel defining layer.

14. The method of claim 13, wherein the mask comprises a plurality of photo spacers, each of the photo spacers abutting against a portion, which is in one of the pixel units, of the pixel defining layer.

15. The method of claim 14, wherein each of the pixel units comprises a first sub-pixel, a second sub-pixel, and a third sub-pixel, the pixel defining layer surrounds the first sub-pixel, the second sub-pixel, and the third sub-pixel;
the opening region of the substrate exposes a light emitting region of the first sub-pixel, the light shielding region of the substrate covers the second sub-pixel, the third sub-pixel, and the pixel defining layer, and at least one of the photo spacers abuts against a portion, between the second sub-pixel and the third sub-pixel in the pixel unit, of the pixel defining layer.

16. A method for preparing a mask, comprising:
forming a substrate comprising an opening region, wherein a region, other than the opening region, of the substrate is a light shielding region; and
forming at least one photo spacer in the light shielding region of the substrate.

17. The method of claim 16, wherein forming the at least one photo spacer comprises:
coating the light shielding region of the substrate with photoresist; and
removing part of the photoresist through exposure and development, such that the remaining photoresist forms the at least one photo spacer.

18. The method of claim 16, wherein forming the at least one photo spacer comprises:
coating the light shielding region of the substrate with photoresist;
removing part of the photoresist through exposure and development;
forming the at least one photo spacer through an electroforming process at a position where the photoresist is removed; and
removing the remaining photoresist.

19. The method of claim 16, wherein forming the substrate comprising the opening region comprises:
coating the substrate with photoresist;
removing part of the photoresist through exposure and development;
forming the opening region through etching at a position where the photoresist is removed; and
removing the remaining photoresist, to form the substrate comprising the opening region.

20. The method of claim 16, wherein forming the substrate comprising the opening region comprises:
coating a base plate with photoresist;
removing part of the photoresist through exposure and development;
forming the light shielding region through an electroforming process at a position where the photoresist is removed; and
removing the remaining photoresist, to form the substrate comprising the opening region.
